(19) United States
(12) Patent Application Publication
(10) Pub. No.: US 2026/0190607 A1
(43) Pub. Date: Jul. 2, 2026

(54) Light Emitting Diode and Light Emitting Display Device

(71) Applicant: LG Display Co., Ltd., Seoul (KR)

(72) Inventors: Yu Jeong Lee, Paju-si (KR); Eun Jung Park, Paju-si (KR); Seung Hyun Kim, Paju-si (KR); Chun Ki Kim, Paju-si (KR)

(21) Appl. No.: 19/350,827

(22) Filed: Oct. 6, 2025

(30) Foreign Application Priority Data
Dec. 31, 2024 (KR) 10-2024-0202837

(51) Int. Cl. H10K 50/13; H10K 50/19

(52) U.S. Cl. CPC H10K 50/131; H10K 50/19

(57) ABSTRACT

Disclosed is a light emitting diode including a first electrode and a second electrode facing each other, and a green light emitting stack including a hole transport layer, a capacitance relieving layer, a green light emitting layer, and an electron transport layer between the first electrode and the second electrode, wherein the capacitance relieving layer contains an auxiliary dopant having a lower HOMO energy level than a green dopant of the green light emitting layer.

### CROSS-REFERENCE TO RELATED APPLICATIONS

This application claims priority under 35 U.S.C. § 119(a) to the Republic of Korea Patent Application No. 10-2024-0202837, filed on Dec. 31, 2024, the entire contents of which are hereby expressly incorporated by reference into the present application.

### TECHNICAL FIELD

The present disclosure relates to a light emitting diode that is imparted with improved image quality and efficiency, and a light emitting display device including the same.

### BACKGROUND

With the advent of the information society, displays for visually expressing electrical information signals have rapidly developed. In response to this, a variety of display devices with excellent performance such as slimness, low weight, and low power consumption are being developed.

There among, a light emitting display device that does not require a separate light source to realize compactness and clear color and has a light emitting diode in a display panel has been considered as a competitive application.

The light emitting diode may include an anode and a cathode facing each other as electrodes, a light emitting layer between the anode and the cathode, and a common layer for transferring holes and electrons to the light emitting layer.

Meanwhile, the light emitting diode may include various functional layers for various functions, for example, in the common layer. The functional layers include a hole transport layer for transferring holes to the light emitting layer and the electron transport layer for transferring electrons to the light emitting layer.

### SUMMARY

Accordingly, the present disclosure is directed to a light emitting diode and a light emitting display device including the same that substantially obviate one or more problems due to limitations and disadvantages of the related art.

The light emitting diode may include light emitting layers that emit light of different colors to express various colors.

Meanwhile, light emitting display devices including different light emitting layers have been problematic in that flashing occurs when a specific color is prominent when switched from a black state to a low-gradation gray state.

It is one object of the present disclosure to provide a light emitting diode that is capable of improving poor image quality in which a specific color is prominent when switched from an off state (black state) to a low-gradation gray state in a structure including light emitting layers that emit light of different colors.

It is another object of the present disclosure to provide a light emitting device display that is capable of reducing an operation voltage of a green light emitting stack that plays a pivotal role in color expression.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a light emitting diode includes a first electrode and a second electrode facing each other, and a green light emitting stack including a hole transport layer, a capacitance relieving layer, a green light emitting layer, and an electron transport layer between the first electrode and the second electrode, wherein the capacitance relieving layer contains an auxiliary dopant having a lower HOMO energy level than the green dopant of the green light emitting layer.

It is to be understood that both the foregoing general description and the following detailed description of the present disclosure are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a cross-sectional view illustrating a light emitting diode according to an embodiment of the present disclosure.

FIG. 2 is an energy band diagram of a third stack of FIG. 1 according to an embodiment of the present disclosure.

FIG. 3A is an energy band diagram of an auxiliary dopant of a capacitance relieving layer and a green dopant of a green light emitting layer.

FIG. 3B illustrates HOMO energy levels and LUMO energy levels of materials for the capacitance relieving layer and the green light emitting layer of FIG. 2.

FIG. 4 illustrates a triplet energy level relationship of the auxiliary dopant and the green dopant.

FIG. 5 is a graph showing luminescence characteristics of the auxiliary dopant and the green dopant.

FIG. 6 is a graph showing JV characteristics of the auxiliary dopant and the green dopant in the HOD device.

FIG. 7 is a graph showing JV characteristics of the auxiliary dopant and the green dopant in the EOD device.

FIG. 8A is a cross-sectional view illustrating the light emitting diode applied to Experimental Example 1;

FIG. 8B is a cross-sectional view illustrating the light emitting diode applied to Experimental Example 2;

FIG. 9 is a graph showing the JV characteristics of Experimental Examples 1 and 2 at a current density of 10 mA/cm² or less.

FIG. 10 is a graph showing the JV characteristics of Experimental Examples 1 and 2 at a current density of 100 mA/cm² or less.

FIG. 11 is a graph showing the change in luminous efficacy depending on the current density of Experimental Examples 1 and 2.

FIG. 12 is a graph showing the intensity depending on the wavelength of Experimental Examples 1 and 2.

FIG. 13 is a graph showing the CV characteristics of Experimental Examples 1 to 3.

FIG. 14 is a graph showing the JV and CV characteristics of Experimental Examples 1 and 2.

FIG. 15 is a graph showing the change in luminance when switching from a black state to a low-gradation gray state in Experimental Examples 4 and 5.

FIG. 16 is a graph showing the change in luminance when switching from a black state to a low-gradation gray state in Experimental Examples 6, 8 and 9.

FIG. 17 is a cross-sectional view illustrating a light emitting display device according to one embodiment of the present disclosure.

FIG. 18 is a cross-sectional view illustrating a light emitting display device according to another embodiment of the present disclosure.

### DETAILED DESCRIPTION

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

Any implementation described herein as an “example” is not necessarily to be construed as preferred or advantageous over other implementations.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship.

Hereinafter, the light emitting device and light emitting display device including the same according to the present disclosure will be described with reference to the drawings.

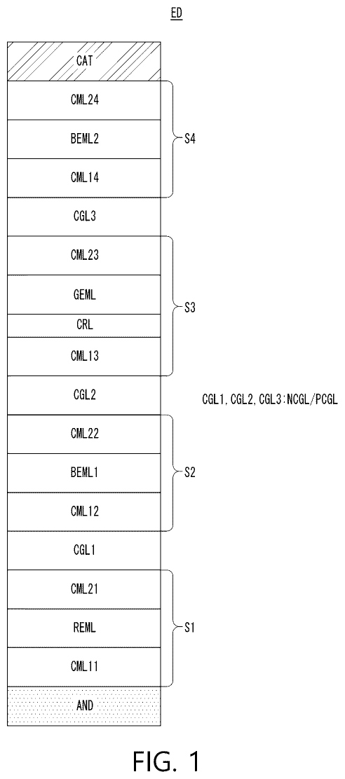

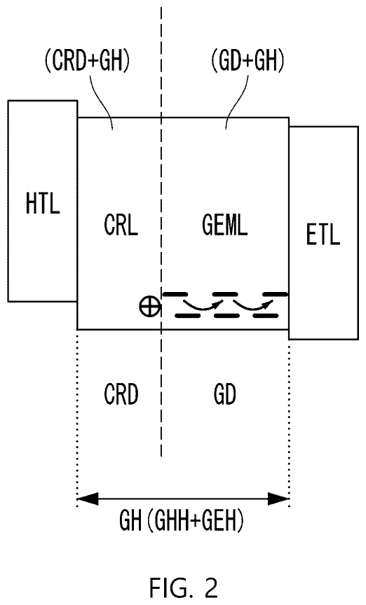

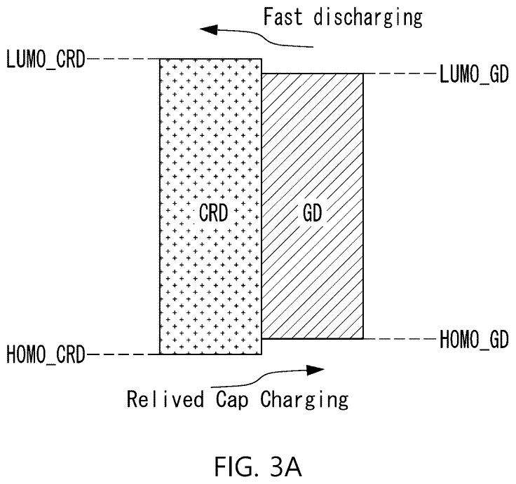

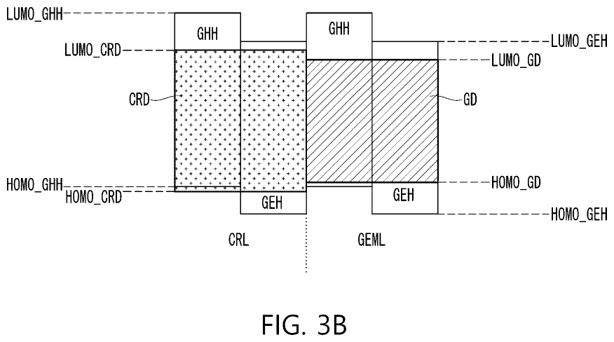

FIG. 1 is a cross-sectional view illustrating a light emitting diode according to an embodiment of the present disclosure. FIG. 2 is an energy band diagram of a third stack of FIG. 1 according to an embodiment of the present disclosure. FIG. 3A is an energy band diagram of an auxiliary dopant of a capacitance relieving layer and a green dopant of a green light emitting layer. FIG. 3B illustrates HOMO energy levels and LUMO energy levels of materials for the capacitance relieving layer and the green light emitting layer of FIG. 2.

A light emitting diode according to an embodiment of the present disclosure is provided in at least one subpixel of a light emitting display device.

As shown in FIG. 1, the light emitting diode ED according to an embodiment of the present disclosure includes a first electrode AND and a second electrode CAT facing each other, and a plurality of light emitting stacks S1, S2, S3, and S4 between the first and second electrodes AND and CAT. The light emitting device may include charge generation layers CGL1, CGL2, and CGL3 between adjacent light emitting stacks among the plurality of light emitting stacks S1, S2, S3, and S4.

The first electrode AND may act as an anode and the second electrode CAT may act as a cathode.

At least one of the first electrode AND and the second electrode CAT is transmissive or semi-transmissive, and transmits light generated in the light emitting diode through the transmissive or semi-transmissive electrode. For example, when the first electrode AND includes a reflective electrode and the second electrode CAT includes a semi-transmissive or transmissive electrode, the light emitting device may emit light through the second electrode CAT. As another example, when the first electrode AND includes a transparent electrode and the second electrode CAT includes a reflective electrode, the light emitting device may emit light through the first electrode AND. As another example, the first electrode AND and the second electrode CAT may be transmissive or semi-transmissive electrodes, so that the light emitting diode ED1 may emit light in both directions of the first electrode AND and the second electrode CAT.

The first electrode AND may be connected to the thin film transistor of the pixel circuit provided in each subpixel on the substrate. The second electrode CAT may be provided in common to each subpixel and may receive a common voltage signal at least from the outside of the non-display area surrounding the subpixels.

Each charge generation layer CGL1, CGL2, and CGL3 may include an n-type charge generation layer NCGL and a p-type charge generation layer PCGL. The n-type charge generation layer NCGL generates electrons and supplies the electrons to adjacent light emitting stacks, and the p-type charge generation layer PCGL generates holes and supplies the holes to adjacent light emitting stacks.

The example illustrated in FIG. 1 shows an example in which four light emitting stacks S1, S2, S3, and S4 are disposed between the first electrode AND and the second electrode CAT, but the embodiments of the present disclosure are not limited thereto. That is, the light emitting devices of the embodiments of the present disclosure may include two light emitting stacks, three or more light emitting stacks, or five or more light emitting stacks between the first electrode AND and the second electrode CAT. When two or more light emitting stacks are included in the light emitting devices of the embodiments of the present disclosure, one light emitting stack may include a green light emitting layer GEML emitting green light.

The light emitting device of FIG. 1 shows an example in which the first light emitting stack S1 includes a red light emitting layer REML, the second light emitting stack S2 includes a first blue light emitting layer BEML1, the third light emitting stack S3 includes a green light emitting layer GEML, and the fourth light emitting stack S4 includes a second blue light emitting layer BEML2.

As such, the light emitting diode ED including light emitting stacks S1, S2, S3, and S4 that emit light with different colors emits white light through at least one of the first electrode AND and the second electrode CAT.

Each of the first to fourth light emitting stacks S1, S2, S3, and S4 has a hole transport common layer CML11, CML12, CML13, CML14 on the lower side of the light emitting layer REML, BEML1, GEML, BEML2 and an electron transport common layer CML21, CML22, CML23, CML24 on the upper side of the light emitting layer REML, BEML1, GEML, or BEML2.

The hole transport common layers CML11, CML12, CML13, CML14 may include a hole injection layer, a hole transport layer (see HTL of FIG. 2), an electron blocking layer, or the like. The hole injection layer may be optionally provided on the first light emitting stack S1 in contact with the first electrode AND. In this case, the hole injection layer may function to transmit holes from the first electrode AND to the red light emitting layer REML. The hole transport layer may transfer holes supplied from the first electrode AND or the charge generation layers CGL1, CGL2, and CGL3 to each of the light emitting layers REML, BEML1, GEML, BEML2. The electron blocking layer may function to block electrons from passing from the light emitting layers REML, BEML1, GEML, BEML2 to the hole transport common layers CML11, CML12, CML13, CML14.

The electron blocking layer may or may not be provided selectively in each of the light emitting stacks S1, S2, S3, and S4.

In some cases, a separate optical compensation layer or a hole transport auxiliary layer may be provided in addition to the hole transport layer or electron blocking layer between the first electrode AND or the charge generation layer CGL1, CGL2, and CGL3, and each of the light emitting layers REML, BEML1, GEML, BEML2.

The hole transport common layer CML11, CML12, CML13, CML14 may include a hole transport material. At least one of the hole transport common layers CML11, CML12, CML13, CML14 may include a plurality of layers including different materials.

The electron transport common layer CML21, CML22, CML23, CML24 may include a hole blocking layer, an electron transport layer (see ETL in FIG. 2), and an electron injection layer. The electron injection layer may be optionally provided in the fourth light emitting stack S4 in contact with the second electrode CAT. In this case, the electron injection layer functions to inject electrons from the second electrode CAT in the direction of the second blue light emitting layer BEML2. The electron transport layer ETL functions to transfer electrons from the second electrode CAT in each light emitting stack in the direction of each light emitting layer. The hole blocking layer functions to restrict holes injected into the light emitting layer from escaping in the direction of the electron transport layer.

The hole blocking layer may or may not be optionally provided in each light emitting stack.

The electron transport common layers CML21, CML22, CML23, CML24 may include an electron transport material. At least one of the electron transport common layers CML21, CML22, CML23, CML24 may be provided in multiple layers including different materials.

The light emitting device of FIG. 1 is implemented as an example in which the first light emitting stack is a red light emitting stack that emits red light, the second light emitting stack is a first blue light emitting stack that emits blue light, the third light emitting stack is a green light emitting stack that emits green light, and the fourth light emitting stack is a second blue light emitting stack that emits blue light, that is, the R/B1/G/B2 light emitting stack is overlapped and disposed in a direction from the first electrode AND to the second electrode CAT, but the light emitting devices of the embodiments of the present disclosure are not limited thereto. For example, when a plurality of light emitting stacks are disposed between the first and second electrodes, unlike the example illustrated in FIG. 1 where they are disposed by color, a red light emitting stack, a green light emitting stack, and first and second blue light emitting stacks (R/G/B1/B2) may be sequentially disposed between the first and second electrodes, or a green light emitting stack, a red light emitting stack, and first and second blue light emitting stacks (G/R/B1/B2) may be sequentially disposed between the first and second electrodes, or a first blue light emitting stack, a red light emitting stack, a green light emitting stack, and a second blue light emitting stack (B1/R/G/B2) may be sequentially disposed between the first and second electrodes, or these stacks may be disposed in another order.

Here, two blue light emitting stacks are disposed in the light emitting device so as to compensate for the relatively low blue efficiency compared to other colors. When two blue light emitting stacks are provided between the first and second electrodes AND and CAT, the second blue light emitting layer BEML2 closer to the second electrode CAT may be thicker than the first blue light emitting layer BEML1 closer to the first electrode AND. This compensates for the efficiency of the second blue light emitting layer BEML2 located at the rear of the first electrode AND (FIG. 1).

The light emitting device including the first to fourth light emitting stacks S1, S2, S3, and S4 described above emits white light when a voltage greater than a predetermined level is applied between the first electrode AND and the second electrode CAT. Each subpixel may further include a color filter outside the first electrode AND or the second electrode CAT from which light is emitted, so that each subpixel renders a different color.

Meanwhile, green has the best visibility and is responsible for the greatest luminance when expressing white, so among the different light emitting stacks, the green light emitting stack requires higher luminous efficacy than the other color light emitting stacks. Accordingly, the green light emitting layer GEML of the green light emitting stack may be thicker and have a larger doping amount than the light emitting layers REML, BEML1, BEML2 of the other color light emitting stacks.

In addition, the green light emitting layer GEML may include a phosphorescent material to increase efficiency.

Referring to FIGS. 2 to 3B, a green light emitting stack according to an embodiment of the present disclosure will be described.

As shown in FIG. 2, the green light emitting stack may sequentially include a hole transport layer HTL, a capacitance relieving layer CRL, a green light emitting layer GEML, and an electron transport layer ETL.

The capacitance relieving layer CRL is disposed adjacent to the hole transport layer HTL before the green light emitting layer GEML.

The capacitance relieving layer CRL contains an auxiliary dopant CRD and a host GH (GHH or GEH).

The green light emitting layer GEML contains a green dopant GD and a host GH (GHH or GEH).

The host GHH and/or GEH contained in the capacitance relieving layer CRL and the green light emitting layer GEML are commonly contained as a hole transport host GHH and an electron transport host GEH. The capacitance relieving layer CRL and the green light emitting layer GEML may include the same material for the host GH (GHH, GEH) and different materials for the auxiliary dopant CRD and the green dopant GD.

As shown in FIG. 3A, the HOMO energy level of the auxiliary dopant CRD is lower than the HOMO energy level of the green dopant GD, and the LUMO energy level of the auxiliary dopant CRD is higher than the LUMO energy level of the green dopant GD. Therefore, the auxiliary dopant CRD has a larger energy band gap than the green dopant GD.

The auxiliary dopant CRD may have a PL (Photoluminescence) peak at a relatively shorter wavelength than a wavelength that a PL peak of the green dopant GD is present at. And the auxiliary dopant CRD may be a type of green light emitting dopant. The auxiliary dopant CRD has a low HOMO energy level between the hole transport layer HTL and the green light emitting layer GEML and thus functions to transfer holes to the green dopant GD and host (GHH, GEH), to increase the efficiency of exciton generation in the green luminescent layer GEML, rather than functioning as a direct luminescent dopant. Therefore, the auxiliary dopant CRD has a main feature of the function of transferring holes to the green luminescent layer GEML rather than direct luminescence of the capacitance relieving layer CRL containing the auxiliary dopant CRD.

In addition, the auxiliary dopant CRD has a lower HOMO energy level than the green dopant GD and is disposed adjacent to the hole transport layer HTL so that holes are not accumulated and are smoothly transferred from the hole transport layer HTL to the green light emitting layer GEML, thereby preventing or reducing carrier charging caused by hole accumulation and reducing green flashing.

The host GHH or GEH in the capacitance relieving layer CRL and the green light emitting layer GEML is contained as a main component, rather than the auxiliary dopant CRD and the green dopant GD, respectively. The auxiliary dopant CRD of the capacitance relieving layer CRL and the green dopant GD of the green light emitting layer GEML are contained in an amount of 5 wt % to 25 wt % of the corresponding layers, respectively.

The HOMO energy level HOMO_CRD of the auxiliary dopant CRD is lower than the HOMO energy level HOMO_GD of the green dopant GD, and the capacitance relieving layer CRL containing the auxiliary dopant CRD is disposed adjacent to the hole transport layer HTL. In this case, holes passing from the hole transport layer HTL to the green light emitting layer GEML are sequentially transferred to the auxiliary dopant CRD and the green dopant GD, and a hole transfer path is generated from the auxiliary dopant CRD to the green dopant GD as well as the hole transport host GHH and the electron transport host GEH, so that holes may be not trapped in the green dopant GD, and the holes passing from the hole transport layer HTL may be sufficiently used for exciton generation, and holes may be prevented or reduced from being trapped near the HOMO energy level of the green dopant GD and accumulating rather than being used for exciton generation. In addition, the hole transport host GHH and the electron transport host GEH are commonly continuous in the capacitance relieving layer CRL and the green light emitting layer GEML, so that the hole flow may be continuous in the capacitance relieving layer CRL and the green light emitting layer GEML.

When the green light emitting layer containing a green dopant GD having a higher HOMO energy level than the host GH (GHH or GEH) directly contacts the hole transport layer, holes are trapped by the relatively shallow HOMO energy level of the green dopant GD and are not used for exciton generation. In addition, since the trapped holes are not easily discharged, in the structure where light emitting stacks emitting light of different colors in sub-pixels accumulate, especially in the green light emitting stack emitting green light, the charging may be aggravated during the process of applying a voltage below the threshold voltage of the light emitting diode. Therefore, green flashing in which green light is prominently displayed when the light emitting diode switches from a black state to a low-gradation gray state may occur.

On the other hand, the light emitting diodes of the embodiments of the present disclosure can solve the charge charging and green flashing problems because the capacitance relieving layer CRL capable of alleviating the phenomenon in which the charges transferred to the green light emitting layer are charged, rather than being used for exciton generation, is disposed between the hole transport layer HTL and the green light emitting layer GEML.

The capacitance relieving layer CRL has a smaller thickness than the green light emitting layer GEML. In addition, the auxiliary dopant CRD contained in the capacitance relieving layer CRL has a HOMO energy level lower than that of the green dopant GD and thus spontaneously transfers energy to the green dopant GD, and has a higher triplet energy level than that of the green dopant GD and thus does not cause reverse energy transfer (bank energy transfer) from the green dopant GD to the auxiliary dopant CRD, thereby avoiding reduction of the efficiency of exciton generation of the green dopant GD in the green light emitting layer GEML. Accordingly, the emission within the green light emitting stack mainly occurs within the green light emitting layer GEML, and the capacitance relieving layer plays major roles in transporting holes and preventing trapping of holes in the green dopant, and does not emit light, or even if it emits light, does not reduce the efficiency of the green light emitting layer GEML. In some cases, the triplet energy level T1_CRD of the auxiliary dopant CRD may be the same as the triplet energy level T1_GD of the green dopant GD.

In addition, the auxiliary dopant CRD has a higher LUMO energy level than the green dopant GD (LUMO_CRD>LUMO_GD), so that electrons can be smoothly transferred from the electron transport layer ETL to the green light emitting layer GEML, rapid discharge is possible when the light emitting diode is switched from the turn-on state to the turn-off state, and defect issues such as afterimages can be prevented or reduced.

The auxiliary dopant CRD may, for example, include an electron-withdrawing group in an iridium phosphorescent dopant matrix. The auxiliary dopant CRD may further include an electron-withdrawing group and thus have a lower HOMO energy level. In addition, the auxiliary dopant CRD may increase the hole mobility more than the green dopant GD.

For example, the green dopant GD may be a phenyl pyridine-based ligand among iridium (Ir)-based complex compounds.

For example, the phosphorescent dopant matrix used in the green dopant GD may include an iridium compound such as Ir(ppy)₃ (tris(2-phenylpyridine)iridium(III)), or Ir(ppy)₂(acac).

The auxiliary dopant CRD according to the embodiment of the present disclosure has both higher hole mobility and electron mobility than the green dopant GD. To this end, the auxiliary dopant CRD may further include an electron withdrawing group than the green dopant GD. The green dopant GD according to the embodiment of the present disclosure may further include an electron withdrawing group, such as a cyano group (—CN) or a fluoro group (—F), in the iridium-based phosphorescent dopant matrix to increase the low HOMO energy level and mobility.

The auxiliary dopant and the green dopant according to the embodiment of the present disclosure will be described in detail based on comparison therebetween with reference to the experiments described below.

The green light emitting layer GEML and the capacitance relieving layer CRL each include a mixed host including a hole transport host GHH and an electron transport host GEH to facilitate the injection and movement characteristics of holes and electrons, as shown in FIG. 3B. In addition, each of these mixed hosts includes a green dopant GD and an auxiliary dopant CRD.

FIG. 3B separately shows a hole transport host GHH and an electron transport host GEH, to show an energy band diagram of the two materials. In fact, the hole transport host GHH and the electron transport host GEH are not separated but mixed at a predetermined ratio within the capacitance relieving layer CRL and the green light emitting layer GEML. Here, the ratio of the hole transport host GHH to the electron transport host GEH means the volume ratio.

In addition, the content of the auxiliary dopant CRD in the capacitance relieving layer CRL and the green dopant GD in the green light emitting layer GEML is smaller than a total content of the hole transport host GHH and the electron transport host GEH. For example, the green dopant GD in the green light emitting layer GEML may be present in an amount of 5 wt % to 25 wt % in the entire green light emitting layer GEML. In addition, the auxiliary dopant CRD in the capacitance relieving layer CRL may be present in an amount of 5 wt % to 25 wt % with respect to the total weight of the capacitance relieving layer CRL.

When holes are injected from the hole transport layer HTL toward the green light emitting layer GEML between the hole transport layer HTL and the green light emitting layer GEML, the capacitance relieving layer CRL has a HOMO energy level lower than that of the green dopant GD and spontaneously transfers green energy to the green dopant GD. In addition, since the auxiliary dopant CRD has a higher triplet energy level and higher mobility than the green dopant GD, energy transfer does not occur in the reverse direction from the green dopant GD to the auxiliary dopant CRD, thereby avoiding a decrease in the efficiency of the green light emitting layer GEML. The capacitance relieving layer CRL contains a luminescent dopant, but has almost no light emission because most of it transfers energy to the green light emitting layer and functions as a hole transport layer.

The HOMO energy level and LUMO energy level according to the present disclosure are evaluated based on the energy level in a vacuum state as 0.0 eV, and both are lower than 0.0 eV, indicating negative values. In comparing two materials, the expression “one material has a deeper energy level” means that it has a lower energy level in the energy diagram and has a larger absolute value.

Therefore, in the embodiments of the present disclosure, the HOMO energy level of the auxiliary dopant CRD is lower than the HOMO energy level of the green dopant GD of the green light emitting layer GEML and thus has a larger absolute value.

Hereinafter, the HOMO energy level and LUMO energy level characteristics of the auxiliary dopant CRD, the hole transport host GHH, and the electron transport host GEH will be compared and described with reference to FIG. 3B.

The HOMO energy level HOMO_CRD of the auxiliary dopant CRD is lower than the HOMO energy level HOMO_GHH of the hole transport host GHH (HOMO_CRD<HOMO_GHH).

In addition, the HOMO energy level HOMO_CRD of the auxiliary dopant CRD is higher than the HOMO energy level HOMO_GEH of the electron transport host GEH (HOMO_CRD>HOMO_GEH).

The LUMO energy level LUMO_CRD of the auxiliary dopant CRD may be lower than the LUMO energy level LUMO_GEH of the electron transport host GEH (LUMO_GEH>LUMO_CRD).

The HOMO energy level HOMO_GD of the green dopant GD may be higher than the HOMO energy level HOMO_GHH of the hole transport host GHH (HOMO_GD>HOMO_GHH).

In addition, the HOMO energy level HOMO_GD of the green dopant GD may be higher than the HOMO energy level HOMO_GEH of the electron transport host GEH (HOMO_GD>HOMO_GEH).

The LUMO energy level LUMO_GD of the green dopant GD may be lower than the LUMO energy level LUMO_GEH of the electron transport host GEH (LUMO_GEH>LUMO_GD).

The capacitance relieving layer CRL is doped with the auxiliary dopant CRD at a content of 5 wt % to 25 wt %. The green light emitting layer GEML is doped with the green dopant GD at a content of 5 wt % to 25 wt %.

Referring to FIG. 3B, the HOMO energy level gradually decreases in the order of the green dopant GD, the hole transport host GHH, and the auxiliary dopant CRD. In addition, the HOMO energy level difference between the green dopant GD and the auxiliary dopant CRD may be 0.25 eV or less.

The HOMO energy level HOMO_CRD of the auxiliary dopant CRD has a difference of 0.15 eV or less from the HOMO energy level HOMO_GHH of the hole transport host. The HOMO energy level HOMO_CRD of the auxiliary dopant CRD is between the HOMO energy level HOMO_GHH of the hole transport host GHH and the HOMO energy level HOMO_GEH of the electron transport host GEH, and has a value closer to the HOMO energy level HOMO_GHH of the hole transport host GHH than that of the electron transport host GEH.

Although the auxiliary dopant CRD has a small difference from the HOMO energy level of the hole transport host GHH, if it has a HOMO energy level lower than the HOMO energy level of the green dopant GD, the phenomenon in which holes are trapped in the green dopant GD due to the difference in properties between the auxiliary dopant CRD and the green dopant GD can be prevented or reduced.

Hereinafter, the differences in properties between the auxiliary dopant CRD and the green dopant GD will be described.

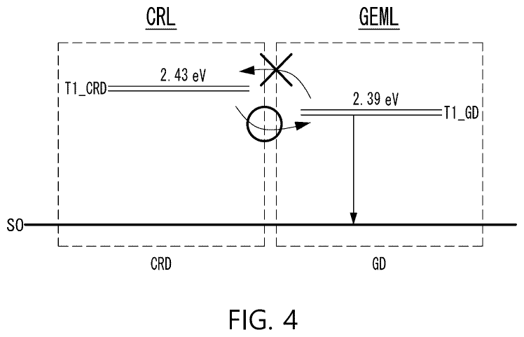

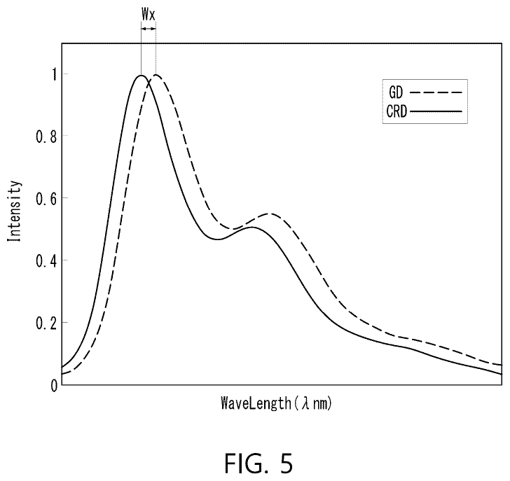

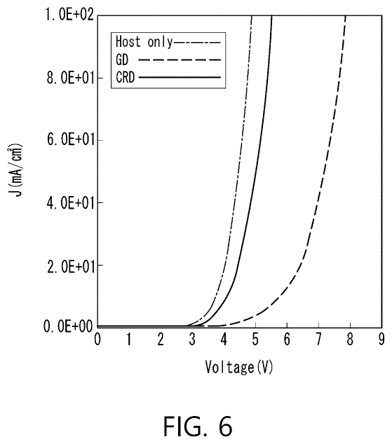

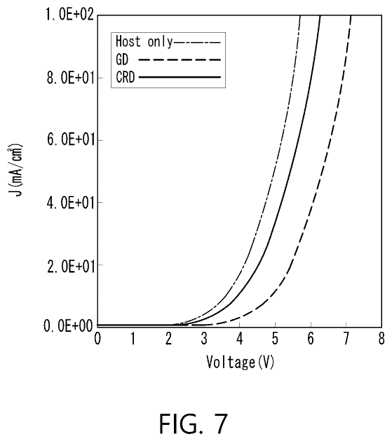

FIG. 4 illustrates the triplet energy level relationship of the auxiliary dopant and the green dopant. FIG. 5 is a graph showing the luminescence characteristics of the auxiliary dopant and the green dopant. FIG. 6 is a graph showing the JV characteristics of the auxiliary dopant and the green dopant in the HOD device. FIG. 7 is a graph showing the JV characteristics of the auxiliary dopant and the green dopant in the EOD device.

As shown in FIG. 4, the auxiliary dopant CRD has a higher triplet energy level than the green dopant GD (T1_CRD>T1_GD).

In the following experiments, the triplet energy level T1_CRD of the auxiliary dopant CRD was 2.43 eV, and the triplet energy level T1_GD of the green dopant GD was 2.39 eV. Here, the auxiliary dopant CRD contained in the capacitance relieving layer CRL has a lower HOMO energy level than the green dopant GD and thus spontaneously transfers energy to the green dopant GD, and has higher triplet energy level than that of the green dopant GD (T1_CRD>T1_GD) and thus prevents or reduces reverse energy transfer (bank energy transfer) from the green dopant GD to the auxiliary dopant CRD. Therefore, the excitons generated from the green dopant GD in the green light emitting layer GEML fall to the ground state S0 and may be used for luminescence. Accordingly, luminescence in the green light emitting stack mainly occurs in the green light emitting layer GEML at a level that does not reduce the efficiency of the green light emitting layer GEML.

As shown in FIG. 5, a PL (Photoluminescence) peak of the auxiliary dopant CRD may be present at a shorter wavelength than a wavelength which a PL peak of the green dopant is present at. The wavelength that the PL peak of the auxiliary dopant CRD is present at may have a difference of 10 nm or less from the wavelength that the PL peak of the green dopant is present at. In a light emitting diode according to one embodiment of the present disclosure, the auxiliary dopant may have an emission peak in a green wavelength band different from a green wavelength band which an emission peak of the green dopant is present at.

In the embodiments of the present disclosure, the capacitance relieving layer CRL includes a hole transport host GHH and an electron transport host GEH, but the auxiliary dopant CRD is not primarily used for luminescence because it is designed to have the function of transferring holes and energy in terms of mobility, triplet energy, and HOMO energy level with the green dopant GD of the adjacent green light emitting layer GEML, and the hole transport host GHH and the electron transport host GEH are designed so that optimal luminescence occurs in the green dopant GD.

FIGS. 6 and 7 show the hole mobility of HOD devices and the electron mobility of EOD devices, when only the host was contained in the active layer, when a green dopant GD was contained in the active layer and when an auxiliary dopant CRD was contained in the active layer.

FIG. 6 shows the electrical characteristics related to holes of the active layer in the HOD (hole only device) including the hole injection layer, the first hole transport layer, the light emitting layer, and the second hole transport layer between the first electrode and the second electrode. Here, the electrical mobility of the light emitting layer was measured and actual light emission was not tested as a major item.

As shown in FIG. 6, when only the hole transport host GHH is included in the light emitting layer of the HOD device and when the auxiliary dopant CRD of the embodiment of the present disclosure is included in the active layer of the HOD device, the current density characteristics of the driving voltage had similar behaviors, but when the green dopant GD is included in the active layer of the HOD device, the current density is significantly lowered at the same driving voltage, and the driving voltage to obtain the same current density is increased.

That is, the hole mobility is higher in the auxiliary dopant CRD of the embodiment of the present disclosure than in the green dopant GD. For example, it can be seen that, based on the driving voltage of 5 V, the current density of the auxiliary dopant CRD is 10 or more times that of the green dopant GD.

The EOD device has a structure including a first electron injection layer, a first electron transport layer, an active layer, a second electron transport layer, and a second electron injection layer between the first electrode and the second electrode, and the electron-related electrical characteristics of the active layer are measured on the EOD device.

As shown in FIG. 7, when only the electron transport host GEH is included in the active layer of the EOD (electron only device) and when the auxiliary dopant CRD of the embodiment of the present disclosure is included in the active layer of the HOD, the current density characteristics for the driving voltage had similar behaviors, but it can be seen that, when the green dopant GD is included in the active layer of the EOD device, the current density is significantly lowered at the same driving voltage. That is, the electron mobility of the auxiliary dopant CRD of the embodiment of the present disclosure is greater than that of the green dopant GD. For example, it can be seen that, based on a driving voltage of 5 V, the current density of the auxiliary dopant CRD has a value that is three times or more that of the green dopant GD.

As such, in the embodiments of the present disclosure, the auxiliary dopant CRD has higher hole mobility and electron mobility under the same conditions than the green dopant GD. Therefore, the auxiliary dopant CRD is included in the capacitance relieving layer CRL adjacent to the green light emitting layer GEML to easily transfer holes to the green dopant GD and to spontaneously transfer energy.

As such, it can be seen that the green dopant according to the embodiment of the present disclosure has a low HOMO energy level and has similar hole mobility to that of the hole transport host and similar electron mobility to that of the electron transport host.

When the auxiliary dopant according to the embodiment of the present disclosure is included in the capacitance relieving layer, the charge mobility increases, so that rapid discharge of carriers is possible in the green light emitting layer when the light emitting device is turned off, and the problem of increased electrostatic capacitance in the off state caused by carriers accumulating in the green light emitting layer due to the provision of the capacitance relieving layer can also be solved. In addition, when rapid discharge is completed in the green light emitting layer in the off state, rapid charging is possible when switching to the on state thereafter, and the flashing phenomenon caused by residual carriers in the light emitting device can be eliminated.

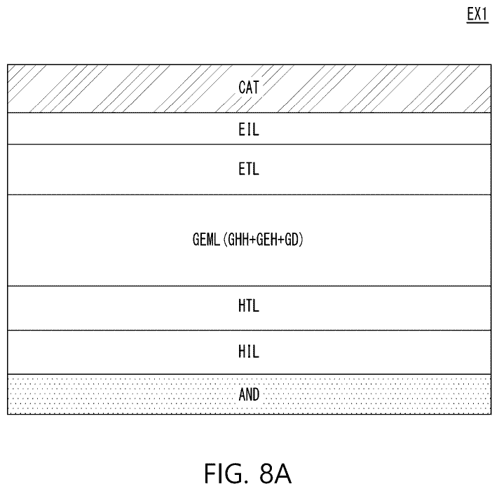

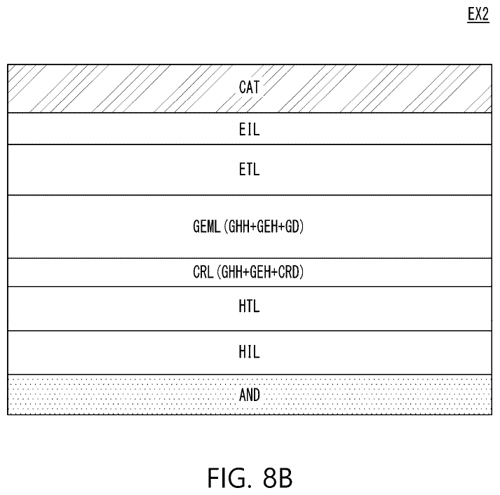

Hereinafter, the significance of the capacitance relieving layer will be described through the structure of Experimental Example 1 EX1 of FIG. 8A including the green light emitting stack between the first and second electrodes and the structure of Experimental Example 2 EX2 of FIG. 8B including the capacitance relieving layer.

FIGS. 8A and 8B are cross-sectional views illustrating the light emitting diodes applied to Experimental Examples 1 and 2.

As shown in FIG. 8A, the light emitting diode EX1 of Experimental Example 1 has a hole injection layer HIL, a hole transport layer HTL, a green light emitting layer GEML, an electron transport layer ETL, an electron injection layer EIL, and a second electrode CAT on the first electrode AND.

Here, the green light emitting layer GEML includes a hole transport host GHH, an electron transport host GEH, and a green dopant GD, as shown in FIGS. 2 to 3.

The thickness of the green light emitting layer GEML was set to 350 Å and the volume ratio of the hole transport host GHH and the electron transport host GEH was set to 7:3. In addition, the green dopant GD was present in an amount of 8 wt % in the mixed host GH of the hole transport host GHH and the electron transport host GEH.

As shown in FIG. 8B, the light emitting diode EX2 of Experimental Example 2 is provided with a hole injection layer HIL, a hole transport layer HTL, a capacitance relieving layer CRL, a green light emitting layer GEML, an electron transport layer ETL, an electron injection layer EIL, and a second electrode CAT on the first electrode AND.

In Experimental Example 2 EX2, the total thickness of the capacitance relieving layer CRL and the green light emitting layer GEML was set to 350 Å, which is the same thickness as the green light emitting layer GEML of Experimental Example 1 EX1. The capacitance relieving layer CRL had a thickness of 150 Å and the green light emitting layer GEML had a thickness of 200 Å.

In addition, in Experimental Example 2 EX2, the components and content ratios of the hole transport host GHH, the electron transport host GEH, and the green dopant GD of the green light emitting layer GEML were the same as in Experimental Example 1 EX1. The capacitance relieving layer CRL differs from the adjacent green light emitting layer GEML in that it includes an auxiliary dopant CRD in addition to the hole transport host GHH and the electron transport host GEH.

Meanwhile, Experimental Example 3 EX3 reversed the positions of the green light emitting layer GEML and the capacitance relieving layer CRL of FIG. 8B. The capacitance relieving layer CRL and the green light emitting layer GEML were formed using the same materials and thickness as Experimental Example 2 EX2.

The HOMO energy level, LUMO energy level, and triplet energy level of the green dopant GD and auxiliary dopant CRD used in the experiments are shown in Table 1 below.

TABLE 1

| Physical properties | HOMO [eV] | LUMO [eV] | T1 [eV] |
|---|---|---|---|
| GD | −5.08 | −2.65 | 2.39 |
| CRD | −5.22 | −2.63 | 2.43 |

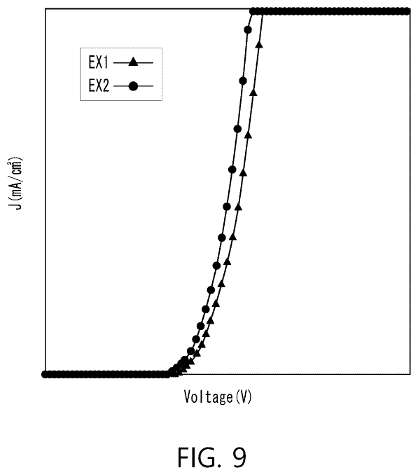

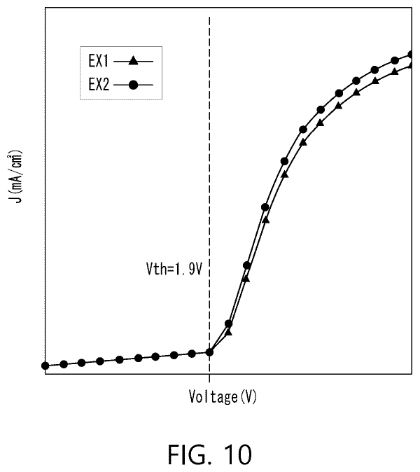

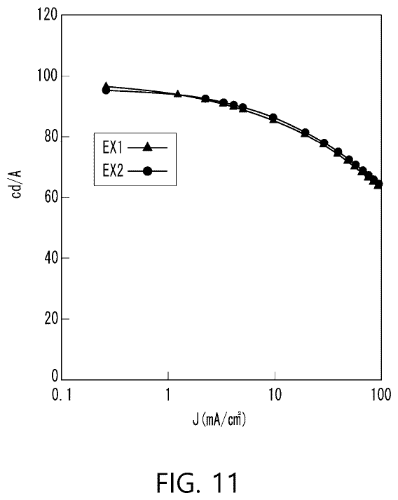

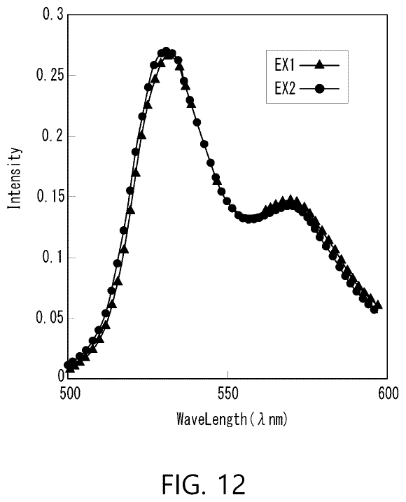

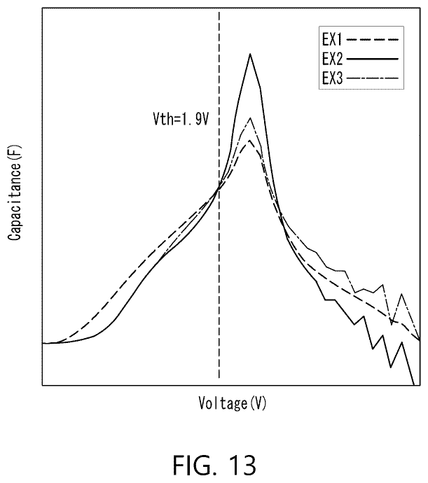

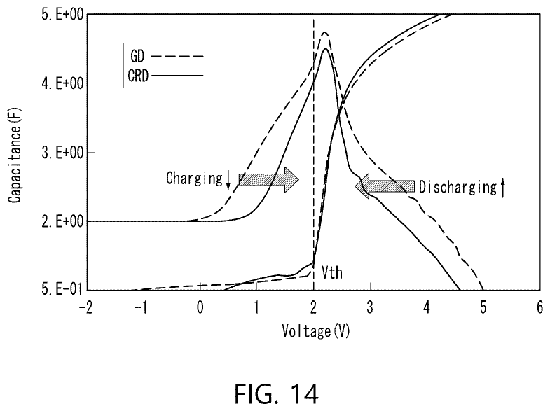

FIG. 9 is a graph showing the JV characteristics of Experimental Examples 1 and 2 at a current density of 10 mA/cm² or less. FIG. 10 is a graph showing the JV characteristics of Experimental Examples 1 and 2 at a current density of 100 mA/cm² or less. FIG. 11 is a graph showing the change in luminous efficacy depending on the current density of Experimental Examples 1 and 2. FIG. 12 is a graph showing the intensity depending on the wavelength of Experimental Examples 1 and 2. FIG. 13 is a graph showing the CV characteristics of Experimental Examples 1 to 3. FIG. 14 is a graph showing the JV and CV characteristics of Experimental Examples 1 and 2.

TABLE 2

| | | IVL (10 mA/cm2) | | | | | | |
|---|---|---|---|---|---|---|---|---|
| | | Voltage[V] | | | | | | Capacitance |
| | Voltage [V] | (@10 | Vth | Cd/A | QE | | | before Vth |
| tem | (@100 mA/cm2) | mA/cm²) | [V] | (%) | (%) | CIEx | CIEy | (%) |
| X1 | Vr1 | Vr2 | 1.9 | 100 | 100 | Cx | Cy | 100 |
| X2 | Vr1 − 0.23 | Vr2 − 0.15 | 1.9 | 101 | 100 | Cx − 0.010 | Cy + 0.007 | 94 |
| X3 | Vr1 + 0.05 | Vr2 + 0.04 | 1.9 | 95 | 95 | Cx − 0.017 | Cy + 0.012 | 94 |

As shown in Table 2 and FIG. 10, the driving voltage was set to the first reference voltage Vr1 at a current density of 100 mA/cm² in Experimental Example 1 EX1, and compared with Experimental Example 2 EX2 and Experimental Example 3 EX3. It can be seen that, when the capacitance relieving layer CRL was provided between the hole transport layer HTL and the green light emitting layer GEML, the driving voltage was reduced by 0.23 V compared to Experimental Example 1 EX1. On the other hand, in Experimental Example 3 EX3 wherein the capacitance relieving layer CRL was disposed between the green light emitting layer GEML and the electron transport layer ETL, the driving voltage increased by 0.05 V compared to Experimental Example 1 EX1.

In addition, as shown in Table 2 and FIG. 9, the driving voltage was set to the second reference voltage Vr2 at a current density of 10 mA/cm² of Experimental Example 1 EX1, and compared with Experimental Example 2 EX2 and Experimental Example 3 EX3. It can be seen that, when the capacitance relieving layer CRL was provided between the hole transport layer HTL and the green light emitting layer GEML, the driving voltage was reduced by 0.15 V compared to Experimental Example 1 EX1. On the other hand, Experimental Example 1 EX1 wherein the capacitance relieving layer CRL was disposed between the green light emitting layer GEML and the electron transport layer ETL EX3 exhibits a 0.04 V increase in driving voltage by compared to Experimental Example 1 EX1.

As can be seen from Table 2 and FIG. 11, the luminous efficiency Cd/A and quantum efficiency QE of Experimental Examples 1 and 2 EX1 and EX2 are substantially similar, or that the luminous efficiency Cd/A and quantum efficiency QE of Experimental Example 2 EX2 is more improved.

In addition, as can be seen from Table 2 and FIG. 12, CIEx and CIEy of Experimental Examples 1 and 2 EX1 and EX2 are slightly different, but the emission spectra have almost similar behaviors.

As can be seen from Table 2 and FIG. 13, the capacitance charged at a voltage below the threshold voltage Vth in Experimental Examples 2 and 3 EX2 and EX3 is reduced in Experimental Example 2 EX2 and Experimental Example 3 EX3 compared to Experimental Example 1 EX1. This is caused by the use of auxiliary dopants.

On the other hand, it can be seen that Experimental Example 2 EX2 has a reduced driving voltage compared to Experimental Example 1 EX1, but exhibits efficiency equal to or higher than Experimental Example 1 EX1, and a 6% or less decrease in capacitance before the threshold voltage, which means that the flashing issue due to charging of charges is prevented or reduced, compared to Experimental Example 1 EX1. On the other hand, Experimental Example 3 EX3 has an increased driving voltage, but reduced efficiency compared to Experimental Example 1 EX1.

That is, the problem in which capacitance is charged before the threshold voltage can be solved by providing a capacitance relieving layer adjacent to the green light emitting layer and Experimental Example 2 EX2 has effects of exhibiting efficiency, driving voltage, and securing color characteristics than Experimental Example 1 EX1 that has a single green light emitting layer by locating the capacitance relieving layer between the hole transport layer and the light emitting layer.

In addition, as can be seen from FIG. 14, the width of the C-V graph in Experimental Example 2 EX2 is smaller than that in Experimental Example 1 EX1. The width of the C-V graph is related to the capacitance charged to the green light emitting layer. When an auxiliary dopant CRD is contained, the capacitance area is reduced, the charged capacitance is reduced and the discharge in an off state is more advantageous compared to the structure using a single green light emitting layer due to the high mobility and low HOMO energy level characteristics of the auxiliary dopant CRD.

Experimental Example 2 EX2 reduces the width of the C-V graph compared to Experimental Example 1 EX1, thereby reducing the charging capacitance and reducing the charging of residual carriers in the green light emitting layer, and at the same time, facilitating rapid discharge when switching from the on state to the off state.

Hereinafter, the change in luminance when switching from a black state to a low-gradation gray state will be described in Experimental Example 4 EX4 in which the green light emitting layer dopant is the green dopant GD described above without a separate capacitance relieving layer in the green light emitting stack, and in Experimental Example 5 EX5 in which the dopant is replaced with an auxiliary dopant CRD with reference to the multiple stack structures including different color light emitting stacks of FIG. 1.

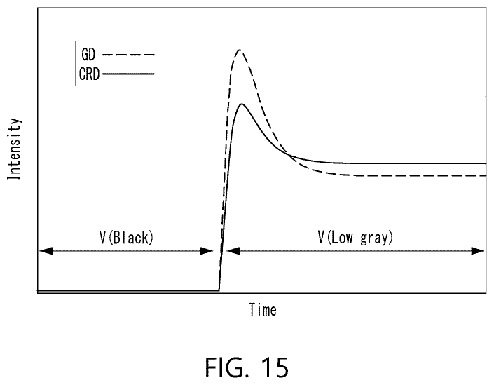

FIG. 15 is a graph showing the change in luminance when switching from a black state to a low-gradation gray state in Experimental Examples 4 and 5.

In the black state, the driving voltage of the light emitting diode was set to 0 V, and in the low-gradation gray state, the driving current was set to generate a current of 0.5 ρA.

Meanwhile, Experimental Example 4 EX4 and Experimental Example 5 EX5 shown in FIG. 15 have a difference in whether the dopant in the green light emitting layer is the green dopant GD of Table 1 or the auxiliary dopant CRD.

As shown in FIG. 15, the luminance intensity of Experimental Example 4 EX4 rapidly increases when switching from a black state to a low-gradation gray state and then decreases to a constant value.

In Experimental Example 5 EX5, the luminance intensity that temporarily changes rapidly when switching from a black state to a low-gradation gray state is reduced compared to Experimental Example 4 EX4, and in Experimental Example 5 EX5, the saturated luminance intensity in the stabilized low-gradation state is greater than that of Experimental Example 4 EX4, so that the difference between the luminance intensity that temporarily changes rapidly and the saturated luminance intensity is reduced and flashing is less visible.

Therefore, the experimental results described above showed that, by incorporating an auxiliary dopant in the capacitance relieving layer, the flashing phenomenon or flashing visibility can be prevented or reduced when switching from a black state to a low-gradation gray state.

In addition, the light emitting diode according to the embodiment of the present disclosure, when the capacitance relieving layer is provided between the hole transport layer of the green light emitting stack and the green light emitting layer, does not trap holes in the green dopant of the green light emitting layer due to the high mobility and low HOMO energy level of the auxiliary dopant, and facilitates hole transfer to the green light emitting layer, and also contributes to exciton generation through spontaneous energy transfer to the green dopant of the adjacent green light emitting layer due to the high triplet energy level characteristic of the auxiliary dopant, so that sufficient exciton generation efficiency can be achieved even with a smaller thickness of the green light emitting layer.

Meanwhile, the light emitting diode of the embodiments of the present disclosure is designed such that an auxiliary dopant is not used as the dopant of the green light emitting layer, and the capacitance relieving layer including the auxiliary dopant is distinguished from the green light emitting layer. Hereinafter, the significance of the thickness of the capacitance relieving layer between the hole transport layer and the green light emitting layer will be described in relation to the lifespan of the light emitting diode.

The following experiments were conducted on the structure of the light emitting device formed by omitting the red light emitting stack in contact with the first electrode AND of FIG. 1 and stacking a first blue light emitting stack (B1), a green light emitting stack (G), and a second blue light emitting stack (B2) in that order between the first electrode AND and the second electrode CAT. Each light emitting stack B1, G, or B2 includes a hole transport common layer, a light emitting layer, and an electron-transporting common layer.

Here, the green light emitting stack is formed as a stack of a hole transport common layer, a green light emitting layer, and an electron transport common layer.

In addition, Experimental Example 6 EX6 includes a single green light emitting layer GEML at the position of the green light emitting layer, Experimental Example 7 EX7 includes a single capacitance relieving layer CRL, and Experimental Examples 8 EX8 to 10 EX10 include the capacitance relieving layer CRL as the front layer and the green light emitting layer GEML as the back layer, but have different thicknesses.

In Experimental Examples 6 to 10 EX6, EX7, EX8, EX9, and EX10, the total thickness of the green light emitting layer GEML and the capacitance relieving layer CRL was commonly set to 350 Å. In Experimental Example 8 EX8 to Experimental Example 10 EX10, the thickness of the capacitance relieving layer CRL was gradually increased to 50 Å, 100 Å, and 150 Å.

TABLE 3

| | Type of | | | | | |
|---|---|---|---|---|---|---|
| | dopant | EX6 | EX7 | EX8 | EX9 | EX10 |
| GEML | GD | 350 | | 300 | 250 | 200 |
| thickness [Å] | | | | | | |
| CRL thickness | CRD | | 350 | 50 | 100 | 150 |
| [Å] | | | | | | |
| Green efficacy Cd/A(%) | | 100.0 | 95.0 | 99.5 | 100.2 | 99.5 |
| Color | Gx | Gx | Gx − 0.028 | Gx − 0.004 | Gx − 0.002 | Gx − 0.005 |
| coordinates | Gy | Gy | Gy + 0.014 | Gy + 0.003 | Gy + 0.002 | Gy + 0.004 |
| 100 mA/cm² | Driving | Vr3 | Vr3 − 0.83 | Vr3 − 0.20 | Vr3 − 0.25 | Vr3 + 0.29 |
| | voltage | | | | | |
| | [V] | | | | | |

| | | | | | |
|---|---|---|---|---|---|
| Green lifespan (%) | 100 | 38 | 89 | 88 | 81 |

As can be seen from Table 3, as in Experimental Example 7 EX7, when the capacitance relieving layer (CRL) is formed as a single layer, the effect of reducing the driving voltage is excellent, but the tendency of reducing the green lifespan is prominent.

Experimental Examples 8, 9 and 10 EX8, EX9, and EX10 exhibit at least 80% green lifespan compared to Experimental Example 6 EX6 provided with a single green light emitting layer GEML, exhibit green efficiency equal to or higher than Experimental Example 6 EX6, and have the effect of reducing the driving voltage.

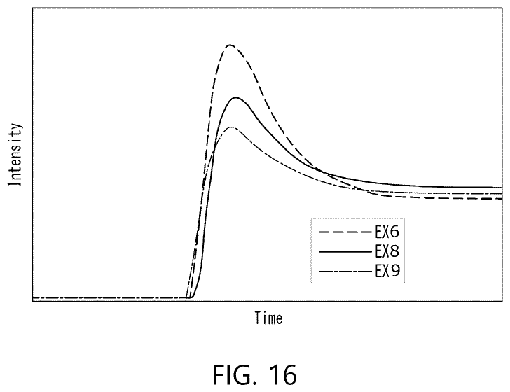

FIG. 16 is a graph showing the change in luminance when switching from a black state to a low-gradation gray state in Experimental Examples 6, 8 and 9.

As can be seen from FIG. 16, in the experimental examples showing comparison in the low-gradation flashing characteristics, the rapid change in luminance when switching from a black state to low-gradation gray can be reduced in experimental example 8 EX8 and experimental example 9 EX9 compared to experimental example 6 EX6, and that the low-gradation flashing can be lowered as the thickness of the capacitance relieving layer is increased.

That is, the experiments of Table 3 and FIG. 16 showed that, when the thickness of the capacitance relieving layer is designed to be less than the thickness of the green light emitting layer and is approximately ⅙ to ¾ of the thickness of the green light emitting layer, the loss of green lifespan can be reduced, and at the same time, the reduction in driving voltage and the low-gradation flashing can be prevented or reduced.

Hereinafter, a light emitting display device according to one embodiment of the present disclosure to which the light emitting diode is applied will be described.

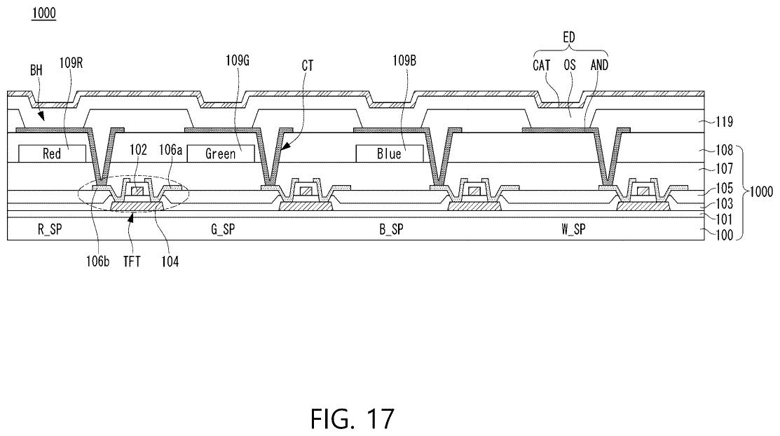

As shown in FIG. 17, the light emitting display device according to an embodiment of the present disclosure may emit light through a first electrode AND on an emission side by applying the light emitting device of FIG. 1 at least one of a plurality of subpixels R_SP, G_SP, B_SP, and W_SP.

The light emitting diode ED of each subpixel may include a first electrode AND, a second electrode CAT, and an intermediate layer OS. The intermediate layer OS may include a plurality of stacks and have the same configuration in the plurality of subpixels R_SP, G_SP, B_SP, W_SP. In addition, the intermediate layer OS may include a configuration having a laminate of a hole transport layer, a capacitance relieving layer, a green light emitting layer, and an electron transport layer in at least a green light emitting stack among a plurality of stacks.

As shown in FIG. 17, the light emitting display device 1000 according to an embodiment of the present disclosure may include a substrate 100 having a plurality of subpixels R_SP, G_SP, B_SP, W_SP, a light emitting diode ED commonly provided on the substrate 100, a thin film transistor TFT provided on each of the subpixels R_SP, G_SP, B_SP, W_SP and connected to the first electrode 110 of the light emitting diode ED, and a color filter layer 109R, 109G, 109B provided under the first electrode 110 of at least one of the subpixels.

FIG. 17 shows an example in which a white subpixel W_SP is included in the light emitting display device, but the present disclosure is not limited thereto, and a structure in which the white subpixel W_SP is omitted and only red, green, and blue subpixels R_SP, G_SP, B_SP are provided is also possible. In some cases, a combination of cyan subpixels, magenta subpixels, and yellow subpixels that can express white by replacing red, green, and blue subpixels is also possible.

The thin film transistor TFT includes, for example, a gate electrode 102, a semiconductor layer 104, and a source electrode 106a and a drain electrode 106b connected to both sides of the semiconductor layer 104. In addition, a channel protection layer may be further provided on an upper portion of a portion where a channel of the semiconductor layer 104 is located to prevent direct connection between the source/drain electrodes 106a, 106b and the semiconductor layer 104. The thin film transistor TFT may include a buffer layer 101 on a substrate 100 and may be located on the buffer layer 101.

A gate insulating film 103 is provided between the gate electrode 102 and the semiconductor layer 104.

The semiconductor layer 104 may be formed of, for example, an oxide semiconductor, amorphous silicon, polycrystalline silicon, or a combination of two or more thereof. For example, when the semiconductor layer 104 is an oxide semiconductor, the heating temperature required to form a thin film transistor may be lowered, so that the substrate 100 may be used with a high degree of freedom, which makes it advantageous for application to a flexible display device.

A gate electrode 102 may be provided on the gate insulating film 103 and an interlayer insulating film 105 may be further provided between the gate electrode 102 and the source electrode 106a/drain electrode 106b.

In addition, the drain electrode 106b of the thin film transistor TFT may be connected to the first electrode 110 and the contact hole CT provided in the first and second protective films 107 and 108.

The first protective film 107 is provided primarily to protect the thin film transistor TFT, and a color filter 109R, 109G, 109B may be provided on the first protective film 107.

A second protective film 108 is provided on the first protective film 107 including the color filter 109R, 109G, 109B.

When a plurality of subpixels includes a red subpixel R_SP, a green subpixel G_SP, a blue subpixel B_SP, and a white subpixel W_SP, as shown in FIG. 17, the color filters are provided as first to third color filters 109R, 109G, 109B for the remaining subpixels R_SP, G_SP, B_SP except for the white subpixel W_SP, so as to allow white light emitted through the first electrode AND to pass according to each wavelength. In addition, a second protective film 108 is formed under the first electrode AND to cover the first to third color filters 109R, 109G, 109B. The first electrode AND is formed on the surface of the second protective film 108 excluding the contact hole CT and is connected to one of the drain electrode 106b and the source electrode 106a of the thin film transistor TFT to receive an electrical signal from the thin film transistor TFT.

Here, the thin film transistor array substrate 1000 may include the substrate 100, the thin film transistor TFT, the color filter 109R, 109G, 109B, and the first and second protective films 107 and 108.

The light emitting diode ED is formed on a thin film transistor array substrate 1000 including a bank 119 defining a light emitting portion BH. The light emitting diode ED may include a transparent first electrode AND, a second electrode CAT of a reflective electrode facing the first electrode AND, and an intermediate layer OS formed between the first electrode AND and the second electrode CAT and may include a plurality of light emitting stacks S1, S2, S3, and S4 and first to third charge generation layers CGL1, CGL2, and CGL3, and a green light emitting layer GEML including a hole transport host GHH, an electron transport host GEH, and a green dopant GD, as shown in FIGS. 2 to 3B, a stack of the capacitance relieving layer CRL and a green light emitting layer GEML that commonly include a hole transport host GHH and an electron transport host GEH between a hole transport layer and an electron transport layer, and a difference configuration in that the capacitance relieving layer CRL includes an auxiliary dopant CRD and the green light emitting layer GEML includes a green dopant GD, may be formed.

Here, the HOMO energy level of the auxiliary dopant CRD may be lower than the HOMO energy level of the green dopant GD.

In addition, the HOMO energy level of the auxiliary dopant CRD may be lower than the HOMO energy level of the hole transport host GHH and higher than the HOMO energy level of the electron transport host GEH, and the LUMO energy level of the auxiliary dopant CRD may be lower than the LUMO energy level of the electron transport host GEH.

In addition, the HOMO energy level of the green dopant GD may be higher than the HOMO energy level of the hole transport host GHH.

The HOMO energy level of the auxiliary dopant CRD may have a difference of 0.15 eV or less from the HOMO energy level of the hole transport host GHH.

The auxiliary dopant CRD may include an electron-withdrawing group in the iridium phosphorescent dopant matrix.

The hole transport host GHH and the electron transport host GEH commonly included in the green light emitting layer GEML and the capacitance relieving layer CRL have the following energy band gap relationship.

That is, the electron transport host GEH has a LUMO energy level lower than the LUMO energy level of the hole transport host GHH (LUMO_GEH<LUMO_GHH), has a HOMO energy level lower than the HOMO energy level of the hole transport host GHH (HOMO_GEH<HOMO_GHH), and the HOMO energy level HOMO_CRD of the auxiliary dopant CRD may be lower than the HOMO energy level HOMO_GHH of the hole transport host (HOMO_CRD<HOMO_GHH).

The HOMO energy level HOMO_CRD of the auxiliary dopant CRD may be closer to the HOMO energy level HOMO_GHH of the hole transport host than to the HOMO energy level HOMO_GEH of the electron transport host (IHOMO_CRD-HOMO_GEHI>IHOMO_CRD-HOMO_GHHI).

The HOMO energy level HOMO_GEH of the electron transport host GEH may be 0.25 eV to 0.55 eV lower than the HOMO energy level HOMO_CRD of the auxiliary dopant CRD.

The thickness of the capacitance relieving layer CRL may be less or smaller than the thickness of the green light emitting layer GEML.

The auxiliary dopant CRD may be present in the capacitance relieving layer CRL in an amount of 5 wt % to 25 wt %, and the green dopant GD may be present in the green light emitting layer GEML in an amount of 5 wt % to 25 wt %.

The HOMO energy level of the green dopant GD, the hole transport host GHH, and the auxiliary dopant CRD may decrease in that order, and the HOMO energy difference between the green dopant GD and the auxiliary dopant CRD may be 0.25 eV or less.

The auxiliary dopant CRD may have a shorter wavelength emission peak than the green dopant GD.

The emission peak of the auxiliary dopant CRD may have an emission peak in a different green wavelength band from the emission peak of the green dopant GD.

The emission peak of the auxiliary dopant CRD may have a difference of 10 nm or less from the emission peak of the green dopant GD.

This shows that the light emitting diode ED of FIG. 17 maintains high green emission efficiency, simultaneously reduces the driving voltage, and prevents or reduces the flashing phenomenon in which green light is observed when switching from the off state to the on state based on the improved charging and discharging characteristics of the light emitting diode.

The first electrode AND is divided into each subpixel, and the remaining layers excluding the first electrode AND of the light emitting diode ED may be provided as an integral part in the entire display area without distinction by subpixel.

Either the first electrode AND or the second electrode CAT may be connected to a thin film transistor TFT.

Meanwhile, the light emitting display device 1000 of FIG. 17 described above is illustrated as a structure in which light is emitted downward, but the present disclosure is not limited thereto. For example, the first electrode AND includes a reflective electrode, the second electrode CAT is a transparent electrode or a reflective-transparent electrode, and the color filter is disposed above the second electrode CAT so that the light emitting display device may be applied in a top-emission manner.

In the structure described above, the intermediate layer OS of the light emitting diode ED is common to each subpixel, but the light emitting display device of the embodiment of the present disclosure is not limited thereto.

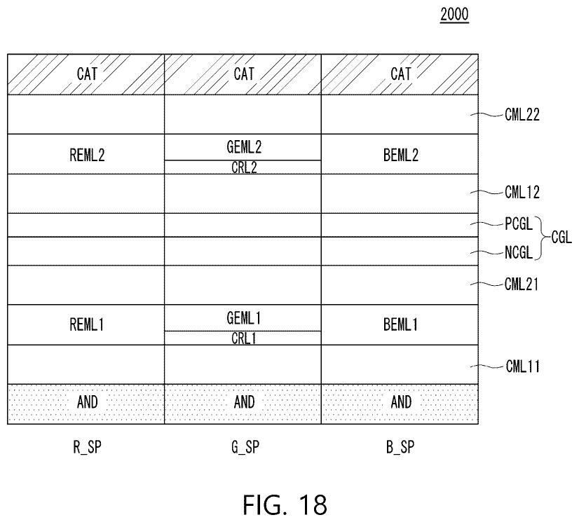

FIG. 18 is a cross-sectional view illustrating a light emitting display device 2000 according to another embodiment of the present disclosure.

As shown in FIG. 18, in addition, the light emitting display device according to another embodiment of the present disclosure may include a first electrode AND and a second electrode CAT facing each of a red subpixel R_SP, a green subpixel G_SP, and a blue subpixel B_SP, and a plurality of light emitting stacks between the first electrode AND and the second electrode CAT, wherein the plurality of light emitting stacks has overlapping light emitting layers that emit the same color. That is, the red subpixel R_SP may have red light emitting layers REML1 and REML2 in separate stacks with a charge generation layer CGL disposed therebetween, the green subpixel G_SP may have green light emitting layers GEML1 and GEML2 in separate stacks with a charge generation layer CGL disposed therebetween, and the blue subpixel B_SP may have blue light emitting layers BEML1 and BEML2 in separate stacks with a charge generation layer CGL disposed therebetween.

Here, a common layer CML11 related to hole injection and hole transport is provided between the first electrode AND and the first red light emitting layer REML1, the first green light emitting layer GEML1, and the first blue light emitting layer BEML1, and a common layer CML21 related to electron transport is provided between the first red light emitting layer REML1, the first green light emitting layer GEML1, and the first blue light emitting layer BEML1 and the charge generation layer CGL.

The charge generation layer CGL may comprise an n-type charge generation layer nCGL and a p-type charge generation layer pCGL.

In addition, a common layer CML12 related to hole injection and hole transport may be provided between the charge generation layer CGL and the second red light emitting layer REML2, the second green light emitting layer GEML2, and the second blue light emitting layer BEML2, and a common layer CML22 including an electron transport layer and an electron injection layer may be provided between the second red light emitting layer REML2, the second green light emitting layer GEML2, and the second blue light emitting layer BEML2 and the second electrode CAT.

The common layers CML11 and CML12 related to hole injection and transport may include at least one of a hole injection layer, a hole transport layer, and an electron blocking layer, and the common layers CML21 and CML22 related to electron transport and injection may include at least one of a hole blocking layer, an electron transport layer, and an electron injection layer.

Here, at least one of the first green light emitting stack disposed on the lower side and the second green light emitting stack disposed on the upper side with the charge generation layer CGL interposed between the green sub-pixel G_SP may include the capacitance relieving layer CRL1 or CRL2 and the green light emitting layer GEML1 or GEML2 described in FIGS. 2 to 3B. Redundant description is omitted.

The green light emitting diode of the green sub-pixel GSP has a predetermined improved luminous efficacy of the green light emitting layer, and can reduce the driving voltage, secure a lifespan of a predetermined level or higher, and prevent or reduces a flashing phenomenon in which green light is observed when switching from an off state to an on state based on the improved charge and discharge characteristics of the green light emitting diode.

The light emitting diode and the light emitting display device including the same according to the embodiment of the present disclosure include a capacitance relieving layer CRL containing an auxiliary dopant CRD having a lower HOMO energy level than a green dopant GD at the front end of a green light emitting layer, so that when holes are injected from a hole transport layer into a green light emitting layer, the phenomenon in which holes are trapped by the green dopant in the green light emitting layer is prevented or reduced, and multiple passes of the green dopant, the hole transport host, and the electron transport host can be formed via the auxiliary dopant.

Since holes or electrons are not trapped by the green dopant and can contribute to the formation of excitons in each host and dopant, the problem of image quality deterioration caused by the charging of residual carriers in the green light emitting layer can be prevented or reduced.

The auxiliary dopant having a low HOMO energy level is provided between the hole transport layer and the green light emitting layer, so that the C-V characteristics that facilitate carrier charging and discharging in the green light emitting layer can be provided and the image quality deterioration caused when the green light emitting layer is turned on/off can be solved.

A light emitting diode according to one embodiment of the present disclosure may comprise a first electrode and a second electrode facing each other and a green light emitting stack comprising a hole transport layer, a capacitance relieving layer, a green light emitting layer, and an electron transport layer between the first electrode and the second electrode. The capacitance relieving layer may contain an auxiliary dopant having a lower HOMO energy level than a green dopant of the green light emitting layer.

In a light emitting diode according to one embodiment of the present disclosure, the capacitance relieving layer may contact the green light emitting layer, and the capacitance relieving layer may contain the same host as that of the green light emitting layer.

In a light emitting diode according to one embodiment of the present disclosure, a hole mobility of the auxiliary dopant may be greater than a hole mobility of the green dopant.

In a light emitting diode according to one embodiment of the present disclosure, a triplet energy level of the auxiliary dopant may be higher than or equal to a triplet energy level of the green dopant.

In a light emitting diode according to one embodiment of the present disclosure, each of the green light emitting layer and the capacitance relieving layer may comprise a hole transport host and an electron transport host. A HOMO energy level of the auxiliary dopant may be lower than a HOMO energy level of the hole transport host and may be higher than a HOMO energy level of the electron transport host. A LUMO energy level of the auxiliary dopant may be lower than a LUMO energy level of the electron transport host.

In a light emitting diode according to one embodiment of the present disclosure, a HOMO energy level of the green dopant may be higher than the HOMO energy level of the hole transport host.

In a light emitting diode according to one embodiment of the present disclosure, a HOMO energy level of the auxiliary dopant may have a difference of 0.15 eV or less from the HOMO energy level of the hole transport host.

In a light emitting diode according to one embodiment of the present disclosure, the auxiliary dopant may comprise an electron-withdrawing group in an iridium phosphorescent dopant matrix.

In a light emitting diode according to one embodiment of the present disclosure, each of the green light emitting layer and the capacitance relieving layer may comprise a hole transport host and an electron transport host. The electron transport host may have a LUMO energy level lower than a LUMO energy level of the hole transport host and a HOMO energy level lower than a HOMO energy level of the hole transport host. The HOMO energy level of the auxiliary dopant may be lower than the HOMO energy level of the hole transport host.

In a light emitting diode according to one embodiment of the present disclosure, the HOMO energy level of the auxiliary dopant may be closer to the HOMO energy level of the hole transport host than to the HOMO energy level of the electron transport host.

In a light emitting diode according to one embodiment of the present disclosure, the HOMO energy level of the electron transport host may be 0.25 eV to 0.55 eV lower than the HOMO energy level of the auxiliary dopant.

In a light emitting diode according to one embodiment of the present disclosure, a thickness of the capacitance relieving layer may be less or smaller than a thickness of the green light emitting layer.

In a light emitting diode according to one embodiment of the present disclosure, the auxiliary dopant may be present in an amount of 5 wt % to 25 wt % in the capacitance relieving layer. The green dopant may be present in an amount of 5 wt % to 25 wt % in the green light emitting layer.

In a light emitting diode according to one embodiment of the present disclosure, the HOMO energy level of the green dopant, the HOMO energy level of the hole transport host, and the HOMO energy level of the auxiliary dopant may decrease in this order. A difference in the HOMO energy level between the green dopant and the auxiliary dopant may be 0.25 eV or less.

In a light emitting diode according to one embodiment of the present disclosure, a PL (Photoluminescence) peak of the auxiliary dopant may be present at a shorter wavelength than a wavelength which a PL peak of the green dopant is present at.

In a light emitting diode according to one embodiment of the present disclosure, the wavelength that the PL peak of the auxiliary dopant is present may have a difference of 10 nm or less from the wavelength that the PL peak of the green dopant is present at.

In a light emitting diode according to one embodiment of the present disclosure, the auxiliary dopant may have an emission peak in a green wavelength band different from a green wavelength band which an emission peak of the green dopant is present at.

In a light emitting diode according to one embodiment of the present disclosure, the light emitting diode may comprise a red light emitting stack comprising a red light emitting layer, a first charge generation layer, a first blue light emitting stack comprising a first blue light emitting layer, and a second charge generation layer between the first electrode and the hole transport layer of the green light emitting stack and a third charge generation layer and a second blue light emitting stack comprising a second blue light emitting layer between the electron transport layer of the green light emitting stack and the second electrode.

In a light emitting diode according to one embodiment of the present disclosure, the green light emitting layer may be thicker than the red light emitting layer, the first blue light emitting layer, and the second blue light emitting layer.

In a light emitting diode according to one embodiment of the present disclosure, a content of the green dopant in the green light emitting layer may be higher than a content of the dopant in each of the red light emitting layer, the first blue light emitting layer, and the second blue light emitting layer.

In a light emitting diode according to one embodiment of the present disclosure, each of the first to third charge generation layers may comprise an n-type charge generation layer and a p-type charge generation layer. The hole transport layer may contact the p-type charge generation layer of the second charge generation layer. The electron transport layer may contact the n-type charge generation layer of the third charge generation layer.

In a light emitting diode according to one embodiment of the present disclosure, the second blue light emitting layer may be thicker than the first blue light emitting layer.

In a light emitting diode according to one embodiment of the present disclosure, two or more green light emitting stacks including the green light emitting stack may be overlapped by interposing a charge generation layer therebetween.

A light emitting display device according to one embodiment of the present disclosure may comprise a substrate including a plurality of subpixels, a pixel circuit at each of the plurality of subpixels, the pixel circuit comprising at least one transistor and the light emitting diode, the light emitting diode connected.

The light emitting device and the light emitting display device including the same according to the present disclosure have the following effects.

The light emitting device and the light emitting display device including the same according to the present disclosure include a capacitance relieving layer including an auxiliary dopant between the hole transport common layer and the green light emitting layer. The auxiliary dopant is a green dopant in the green light emitting layer or has a low HOMO energy level, so that, when holes are injected from the hole transport common layer to the green light emitting layer, the holes are not directly trapped in the green dopant, but are sequentially transferred to the green dopant in the green light emitting layer via the auxiliary dopant in the capacitance relieving layer. Therefore, holes transferred from the hole transport common layer to the green light emitting layer via the capacitance relieving layer are not trapped in the green dopant, and a hole transfer path is generated to the hole transport host and electron transport host in the green light emitting layer and charges are prevented or reduced from accumulating in the green light emitting layer.

Since holes or electrons are not trapped in the green dopant, but contribute to the formation of excitons in each host and dopant, the problem of image quality deterioration caused by residual carriers being charged in the green light emitting layer can be prevented or reduced. That is, it is possible to prevent or reduce the flashing phenomenon in which green is prominently observed when switching from the off state to the low-gradation gray state caused by residual carriers in the green light emitting layer.

The capacitance relieving layer provided between the hole transport common layer and the green light emitting layer prevents or reduces residual carriers in the green light emitting layer, thus facilitating carrier discharge when switching from the turn-on state to the turn-off (black state), and also facilitating carrier transfer between each material in the green light emitting layer from the auxiliary dopant when switching from a turn-off (black state) to a turn-on state, enabling rapid charging in the turn-on state and lowering the driving voltage when turned on. Therefore, the capacitance relieving layer solves the degradation of image quality that occurs when switching the green light emitting layer on/off by providing the C-V (capacitance-voltage) characteristics that facilitates charging and discharging of carriers when the green light emitting layer is turned on-off.

The light emitting diode and light emitting display device according to the embodiments of the present disclosure prevent or reduce formation of residual carriers generated caused by holes trapped in a specific material in the light emitting layer and improve the charge-discharge characteristics at turn-on and turn-off, thus having the advantages of solving the flashing issue, reducing the driving voltage and being continuously applicable. Accordingly, the light emitting diode and light emitting display device according to the embodiments of the present disclosure are capable of achieving ESG (environmental/social/governance) goals.

It will be apparent to those skilled in the art that various modifications and variations may be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting diode comprising:
a first electrode and a second electrode facing each other; and
a green light emitting stack comprising a hole transport layer, a capacitance relieving layer, a green light emitting layer, and an electron transport layer between the first electrode and the second electrode,
wherein the capacitance relieving layer comprises an auxiliary dopant having a lower HOMO energy level than a green dopant of the green light emitting layer.

2. The light emitting diode according to claim 1, wherein the capacitance relieving layer contacts the green light emitting layer, and
wherein the capacitance relieving layer comprises a same host as that of the green light emitting layer.

3. The light emitting diode according to claim 1, wherein a hole mobility of the auxiliary dopant is greater than a hole mobility of the green dopant.

4. The light emitting diode according to claim 1, wherein a triplet energy level of the auxiliary dopant is higher than or equal to a triplet energy level of the green dopant.

5. The light emitting diode according to claim 1, wherein each one of the green light emitting layers and the capacitance relieving layer comprises a hole transport host and an electron transport host,
wherein a HOMO energy level of the auxiliary dopant is lower than a HOMO energy level of the hole transport host and is higher than a HOMO energy level of the electron transport host, and
wherein a LUMO energy level of the auxiliary dopant is lower than a LUMO energy level of the electron transport host.

6. The light emitting diode according to claim 5, wherein a HOMO energy level of the green dopant is higher than the HOMO energy level of the hole transport host.

7. The light emitting diode according to claim 5, wherein the HOMO energy level of the auxiliary dopant has a difference of 0.15 eV or less from the HOMO energy level of the hole transport host.

8. The light emitting diode according to claim 1, wherein the auxiliary dopant comprises an electron-withdrawing group in an iridium phosphorescent dopant matrix.

9. The light emitting diode according to claim 1, wherein each one of the green light emitting layers and the capacitance relieving layer comprises a hole transport host and an electron transport host,
wherein the electron transport host has a LUMO energy level lower than a LUMO energy level of the hole transport host and a HOMO energy level lower than a HOMO energy level of the hole transport host, and
wherein the HOMO energy level of the auxiliary dopant is lower than the HOMO energy level of the hole transport host.

10. The light emitting diode according to claim 9, wherein the HOMO energy level of the auxiliary dopant is closer to the HOMO energy level of the hole transport host than to the HOMO energy level of the electron transport host.

11. The light emitting diode according to claim 5, wherein the HOMO energy level of the electron transport host is by 0.25 eV to 0.55 eV lower than the HOMO energy level of the auxiliary dopant.

12. The light emitting diode according to claim 1, wherein a thickness of the capacitance relieving layer is smaller than a thickness of the green light emitting layer.

13. The light emitting diode according to claim 1, wherein the auxiliary dopant is present in an amount of 5 wt % to 25 wt % in the capacitance relieving layer, and
wherein the green dopant is present in an amount of 5 wt % to 25 wt % in the green light emitting layer.

14. The light emitting diode according to claim 5, wherein the HOMO energy level of the green dopant, the HOMO energy level of the hole transport host, and the HOMO energy level of the auxiliary dopant decrease in this order, and
wherein a difference in the HOMO energy level between the green dopant and the auxiliary dopant is 0.25 eV or less.

15. The light emitting diode according to claim 1, wherein a PL (Photoluminescence) peak of the auxiliary dopant is present at a shorter wavelength than a wavelength which a PL peak of the green dopant is present at.

16. The light emitting diode according to claim 15, wherein the wavelength that the PL peak of the auxiliary dopant is present at has a difference of 10 nm or less from the wavelength that the PL peak of the green dopant is present at.

17. The light emitting diode according to claim 1, wherein the auxiliary dopant has an emission peak at a green wavelength band different from a green wavelength band which an emission peak of the green dopant is present at.

18. The light emitting diode according to claim 1, wherein the light emitting diode comprises:
a red light emitting stack comprising a red light emitting layer;
a first charge generation layer;
a first blue light emitting stack comprising a first blue light emitting layer;
a second charge generation layer between the first electrode and the hole transport layer of the green light emitting stack;
a third charge generation layer; and
a second blue light emitting stack comprising a second blue light emitting layer between the electron transport layer of the green light emitting stack and the second electrode.

19. The light emitting diode according to claim 18, wherein the green light emitting layer is thicker than the red light emitting layer, the first blue light emitting layer, and the second blue light emitting layer.

20. The light emitting diode according to claim 18, wherein a content of the green dopant in the green light emitting layer is higher than a content of a dopant in each of the red light emitting layer, the first blue light emitting layer, and the second blue light emitting layer.

21. The light emitting diode according to claim 18, wherein each of the first to third charge generation layers comprises an n-type charge generation layer and a p-type charge generation layer,
wherein the hole transport layer contacts the p-type charge generation layer of the second charge generation layer, and
wherein the electron transport layer contacts the n-type charge generation layer of the third charge generation layer.

22. The light emitting diode according to claim 18, wherein the second blue light emitting layer is thicker than the first blue light emitting layer.

23. The light emitting diode according to claim 1, wherein two or more green light emitting stacks including the green light emitting stack are overlapped by interposing a charge generation layer between the two or more green light emitting stacks including the green light emitting stack.

24. A light emitting display device comprising:
a substrate including a plurality of subpixels;
a pixel circuit at each of the plurality of subpixels, the pixel circuit comprising at least one transistor; and
the light emitting diode according to claim 1, the light emitting diode connected to the pixel circuit in at least one of the subpixels.
